(19) United States
(12) Patent Application Publication
(10) Pub. No.: US 2003/0017258 A1
(43) Pub. Date: Jan. 23, 2003

(54) Method of manufacturing electroluminescence display apparatus

(76) Inventors: Tsutomu Yamada, Motosu-gun (JP); Ryuji Nishikawa, Gifu-shi (JP); Susumu Oima, Anpachi-gun (JP)

Correspondence Address: CANTOR COLBURN, LLP, 55 GRIFFIN ROAD SOUTH, BLOOMFIELD, CT, 06002

(21) Appl. No.: 10/183,149

(22) Filed: Jun. 27, 2002

(30) Foreign Application Priority Data
Jun. 29, 2001 (JP) 2001-198923

(51) Int. Cl. H05B 33/10

(52) U.S. Cl. 427/66; 428/917; 313/504; 313/505; 257/89

(57) ABSTRACT

In manufacturing an electroluminescence display apparatus, after a substrate and a mask disposed below the substrate are aligned with each other, a material of an electroluminescence element is adhered to the substrate through an opening of the mask to form an electroluminescence element layer. Alignment of the substrate and the mask is performed while an upper surface of the substrate is supported by adsorption. Because the substrate is supported by adsorption during the alignment of the substrate and the mask, the flexure in the substrate can be inhibited. When a plurality of pins are provided on the mask side or the sides of the substrate are further supported by side supporting members, occurrence of flexure in the substrate can be more reliably inhibited.

### BACKGROUND OF THE INVENTION

1. Field of the Invention

The present invention relates to a method of manufacturing an electroluminescence (EL) display apparatus, and more particularly to a method of manufacturing an EL display apparatus, in which an EL element is formed on a substrate surface using a mask.

2. Description of Related Art

In recent years, display apparatuses using an EL element have attracted great attention.

Such an EL element may be constituted, for example, by an anode formed by a transparent electrode made of ITO (Indium Tin Oxide) or the like, a hole transporting layer made of MTDATA (4,4′,4″-tris(3-methylphenylphenylamino)triphenylamine) or TPD (N,N′-diphenyl-N,N′-di(3-methylphenyl)-1,1′-biphenyl-4,4′-diamine), an emissive layer made of BeBq₂ (bis(10-hydroxybenzo[h]quinolinato)beryllium) including quinacridone derivative or the like, an electron transporting layer made of BeBq₂ or the like, and an electrode (cathode) made of a magnesium indium alloy or the like, which are sequentially accumulated in a laminate structure. In such an EL element, holes injected from the anode and electrons introduced from the cathode are recombined in the emissive layer when a required voltage is applied between these electrodes, to thereby excite organic molecules forming the emissive layer to generate excitons. Through the process in which these excitons radiate until deactivation, the emissive element projects light which is directed externally from the transparent anode through the transparent insulating substrate, whereby desired emission is obtained.

When a display apparatus using such an EL element, i.e. an EL display apparatus, is constituted as a color image display apparatus, the EL display apparatus has a structure of a dot matrix display apparatus in which EL elements each emitting light corresponding to one of three colors, for example, red (R), green (G), and blue (B) are arranged in a matrix. In order to drive these EL elements arranged in a dot matrix pattern, a passive matrix method or an active matrix method can be employed.

In the passive matrix method, the EL elements arranged in a matrix pattern on the display panel to form respective pixels are directly driven externally in synchronization with a scanning signal. In this case, the display region in the display apparatus is constituted only by the EL elements.

In the active matrix method, on the other hand, a pixel driving element (an active element) is provided for each of the EL elements arranged in a matrix to form the respective pixels. The pixel driving element acts as a switch element which switches between on and off states in accordance with a scanning signal. The EL element is driven in such a manner that a data signal (a display signal or a video signal) is transmitted to the anode of the EL element through the pixel driving element which is in the on state, and predetermined current corresponding to the data signal flows between the anode and cathode of the EL element.

For the formation of EL elements used in such a display apparatus, a vacuum evaporation process is often employed. The formation of an EL element using the vacuum evaporation process basically includes the following two steps:

(1) within a vacuum chamber, covering, with a mask, portions of a substrate other than portions where EL elements are to be formed and placing the substrate such that the masked surface faces in the vertically downward direction; and

(2) heating a material for forming the EL element, including a material of an emissive layer or the like, to evaporate the material from under the substrate, thereby depositing the material on the substrate surface and forming the EL element.

In order to form the EL element on the substrate surface in the above-described manner, it is necessary, especially for the formation of the emissive layer, to very accurately align the substrate and the mask. However, if at the time of alignment the substrate is supported in such manner that the EL element forming surface of the substrate constitutes a lower surface which faces downward, it is not possible to dispose this lower surface in direct contact with the mask because most of the lower surface forms the display panel region on which the EL element or the like is to be formed. In other words, it is necessary to support the end portions of the substrate, regions other than the display panel region with an appropriate support hand or the like. When the end portions of the substrate are supported, however, flexure is likely to be generated in the center portion of the substrate. As a result, when the substrate is moved toward the mask side, the center portion of the substrate first comes into contact with the mask. If, under this state, the substrate and the mask are moved relative to each other so as to make alignment, there is a possibility that the film surface of the substrate is damaged, and accurate alignment cannot be obtained.

On the other hand, from the standpoint of the accuracy of alignment and of film deposition, it is desirable to place the substrate and the mask as close to each other as possible, which further exacerbates the above problem.

Further, the above-described problem that flexure in the substrate makes alignment difficult occurs not only with the vacuum evaporation process but also when the EL element is formed by other methods. Therefore, this problem is generally in common in various manufacturing methods as long as accurate alignment is required between the substrate and the mask.

### SUMMARY OF THE INVENTION

The present invention was conceived in view of the above described problems of the related art and an object of the present invention is to enable more accurate alignment between a mask and a substrate when forming an electroluminescence element using a mask.

In accordance with one aspect of the present invention, there is provided a method of manufacturing an electroluminescence display apparatus, in which after a substrate and a mask disposed below the substrate are aligned with each other while an upper surface of the substrate is supported by adsorption, a material of an electroluminescence element is adhered to the substrate through an opening of the mask to form an electroluminescence element layer.

By adsorbing and supporting an upper surface of the substrate which is located on the mask during the alignment of the substrate with the mask as described above, it is possible to inhibit flexure generated in the mask and thereby enhance the accuracy of the alignment. It is also possible to prevent the element forming surface side of the substrate being damaged by the mask during the alignment, as would otherwise be caused were the element forming surface to bend and contact the mask disposed below.

In accordance with another aspect of the present invention, the mask may be fixed and positioned prior to the alignment of the substrate and the mask, and the substrate which is supported by adsorption may be moved so that the substrate is aligned with the mask. Further, the mask may be fixed and positioned onto a mask frame which is disposed on a holding table.

In this manner, by fixing the mask side in advance, and then moving the substrate side which is supported by adsorption in such a manner that generation of flexure is inhibited so as to align the substrate with the mask, the alignment can be performed more accurately with a simple mechanism.

In accordance with another aspect of the present invention, at least the alignment of the substrate and the mask may be performed within a vacuum chamber. The vacuum chamber may be, for example, an evaporation chamber for the electroluminescence element layer.

According to the method of the present invention, alignment of a mask and a substrate can be performed even in a vacuum chamber. Further, when a substrate is aligned with a mask used in evaporation of an electroluminescence element material within an evaporation chamber (a vacuum evaporation chamber) for the electroluminescence element as described above, it is possible to start the process of forming an element layer immediately after completion of the alignment. It is therefore possible to form the element layer by evaporation quickly and accurately without changing the relative positions of the mask and the substrate after the alignment.

In accordance with another aspect of the present invention, when the alignment of the substrate and the mask is performed within a vacuum chamber as described above, an upper surface of the substrate may be supported by adsorption using an electrostatic adsorption mechanism.

When the substrate is supported by an electrostatic adsorption mechanism, the substrate can be reliably supported without generating flexure, even within a vacuum chamber.

In accordance with another aspect of the present invention, at least three sides of the substrate are further supported by side supporting members during the alignment of the substrate and the mask.

At the time of the alignment, by further supporting the substrate using the side supporting members in addition to the pins, the flexure in the substrate can be inhibited more reliably.

In accordance with another aspect of the present invention, the mask is fixed and positioned on a mask frame prior to the alignment of the substrate and the mask, and the substrate is then aligned with the mask while the substrate which is supported by adsorption is further supported on the mask using a plurality of pins provided on the mask frame.

In accordance with still another aspect of the present invention, the mask is fixed and positioned on a mask frame disposed on a supporting table prior to the alignment of the substrate and the mask, and the substrate is then aligned with the mask while the substrate which is supported by adsorption is further supported on the mask using a plurality of pins provided on at least one of the mask frame and the supporting table.

As described above, when the substrate which is supported by adsorption is further supported by a plurality of pins formed on the mask side (the mask frame or the supporting table) disposed below the substrate during the alignment, it is possible to support the flexure caused by the weight of the substrate also from below the substrate, thereby more reliably inhibiting occurrence of flexure in the substrate. This in turn makes it possible to further enhance the accuracy of the alignment, and the possibility that the element forming surface side of the substrate is bent and is damaged by the mask during the alignment can be more reliably prevented.

In accordance with another aspect of the present invention, the plurality of pins are capable of expansion and contraction in a vertical direction.

By using pins capable of expansion and contraction as described above, when the substrate contacts these pins disposed below, that is when the substrate is supported by the pins, each of the pins can be contracted in accordance with a force generated by the weight of the substrate, thereby simplifying the inhibition of slight winding and flexure in the element forming surface of the substrate.

### BRIEF DESCRIPTION OF THE DRAWINGS

These and other objects of the invention will be explained in the description below, in connection with the accompanying drawings, in which:

FIG. 1 is a plan view of an active matrix type EL display apparatus as seen from above;

FIGS. 2A and 2B are cross sectional views each showing a partial sectional structure of an active matrix type EL display apparatus;

FIG. 3 is a flowchart showing manufacturing procedures in a method of manufacturing an EL display apparatus according to a first embodiment of the present invention;

FIG. 4 is a perspective view showing alignment of a mask and a glass substrate in a vacuum chamber in accordance with the first embodiment of the present invention;

FIG. 5 is a plan view showing disposition of a mask and a glass substrate according to the first embodiment;

FIG. 6 is a side view schematically showing formation of an EL element by evaporation according to the first embodiment;

FIGS. 7A, 7B, and 7C are diagrams for explaining the relationship between the size and support type of a glass substrate and the flexure generated in the glass substrate;

FIG. 8 is a cross sectional view schematically showing support of a glass substrate according to the first embodiment of the present invention;

FIG. 9 is a cross sectional view showing support of a glass substrate according to a second embodiment of a method of manufacturing an EL display apparatus of the present invention;

FIG. 10 is a perspective view showing support of a glass substrate according to a third embodiment of a method of manufacturing an EL display apparatus of the present invention;

FIG. 11 is a flowchart showing the procedures for formation of an EL element by evaporation according to the third embodiment; and

FIG. 12 is a plan view showing support of a glass substrate as a modification example of the above embodiments.

FIG. 13 is a view showing an example in which a glass substrate is supported in another manner in each of above embodiments.

### DETAILED DESCRIPTION OF THE PREFERRED EMBODIMENTS

(First Embodiment)

A first embodiment of a method of manufacturing an EL display apparatus of the present invention, which is implemented as a method of manufacturing an active matrix type color EL display apparatus, will be described with reference to the drawings.

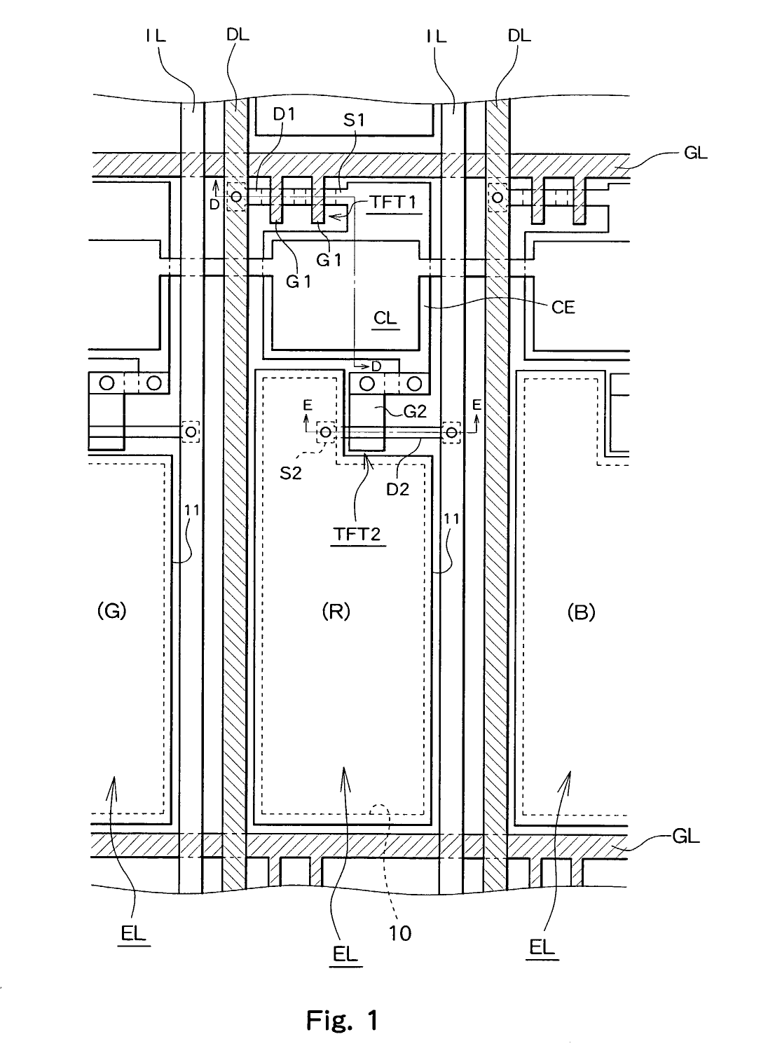

FIG. 1 is a plan view of an EL element (which is an organic EL element in this embodiment and is indicated as “EL” in FIG. 1) and its peripheral section, of an EL display apparatus to be manufactured according to the present embodiment. Referring to FIG. 1, the EL display apparatus comprises a display pixel formed by the EL element, and a thin film transistor (TFT) which is an active element provided for each corresponding display dot.

More specifically, as shown in FIG. 1, gate signal lines GL and drain signal lines (data signal lines) DL are arranged in a matrix as signal lines for performing drive control of the EL element. An EL element (display pixel) is provided corresponding to each intersection of these signal lines. In the EL display apparatus shown in FIG. 1, each display pixel corresponds to any one of the primary colors R, G and B, to thereby enable color image display.

Additional elements are also provided so as to perform drive control of each of the EL elements separately. First, near the above-described intersection of the signal lines, a thin film transistor (TFT1), which is connected with the gate signal line GL and functions as a switching element to be turned ON due to the activity of the gate signal line GL, is formed. A source S1 of this TFT1 serves also as a capacitor electrode CE and a storage capacitor is formed between the capacitor electrode CE and a capacitor line CL made of a refractory metal such as chromium (Cr) and molybdenum (Mo). When the TFT1 is turned ON, an electrical charge in accordance with the voltage of a data signal supplied from the data line DL is accumulated in the storage capacitor.

The capacitor electrode CE is connected to a gate G2 of a thin film transistor (TFT2) which drives the EL element. Further, a source S2 of the TFT2 is connected with a transparent electrode 11 which is an anode of the EL element, while a drain D2 of the TFT2 is connected with a drive power source line IL which is a current source for supplying an electrical current to the EL element. With this structure, a voltage in accordance with the electrical charge stored in the storage capacitor is applied from the capacitor electrode CE to the gate G2, such that a current in accordance with the applied voltage is supplied from the drive power source line IL to the EL element.

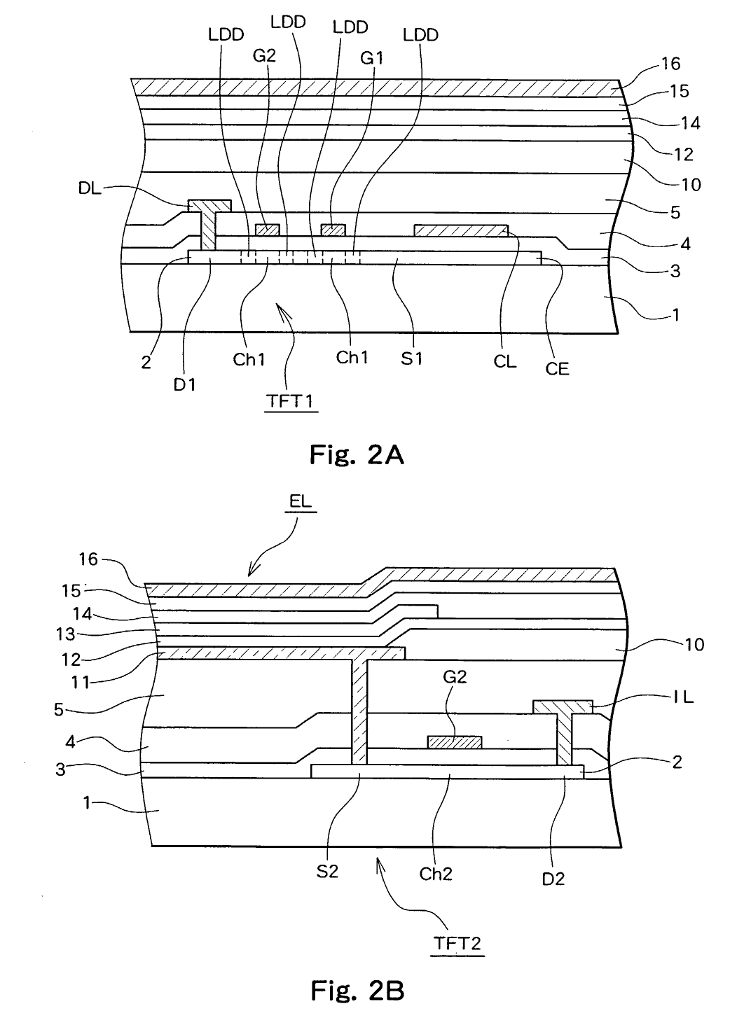

FIGS. 2A and 2B are cross sectional views taken along lines D-D and E-E of FIG. 1, respectively. As shown in FIGS. 2A and 2B, the above-described EL display apparatus is formed by sequentially forming a thin film transistor and an EL element on a glass substrate 1 in a laminated structure.

First, the TFT1 which serves as a switching transistor for performing charging control of the storage capacitor is formed in a manner shown in FIG. 2A. Specifically, on the glass substrate 1, a poly-silicon layer 2 is formed. In this poly-silicon layer 2, the above-described source S1 and the drain D1 as well as channels Ch1 are formed, while LDDs (Lightly Doped Drains) are further provided on both outer sides of the channels Ch1. The poly-silicon layer 2 also serves as a storage capacitor electrode CE. On the poly-silicon layer 2 and the storage capacitor electrode CE, a gate insulating film 3, the above-described gate signal line GL made of a refractory metal such as Cr and Mo and a gate electrode G1 which is integral with the gate signal line GL, and a storage capacitor electrode line CL are formed. Further, over these layers, an interlayer insulating film 4 formed by accumulating a silicon oxide film and silicon nitride film, in this order, in a laminate structure is provided. This interlayer insulating film 4 has an opening at a position corresponding to the drain D1. By filling this opening with a conductive material such as aluminum, the drain D1 comes into electrical contact with the drain signal line DL. Further, on these drain signal line DL and the interlayer insulating film 4, a planarization insulating film 5 made of, for example, an organic resin, is formed for surface planarization.

On the other hand, the TFT2 for driving the EL element is formed in a manner as shown in FIG. 2B. Specifically, on the glass substrate 1, a poly-silicon layer 2 which is equal to that shown in FIG. 2A is formed. In this poly-silicon layer 2, a channel Ch2, a source S2, and a drain D2 of the TFT2 are formed. On this poly-silicon layer 2, a gate insulating film 3 which is equal to that shown in FIG. 2A is formed, and on the portion of the gate insulating film 3 which is located above the channel Ch2, a gate G2 made of a refractory metal such as chromium (Cr) and molybdenum (Mo) is provided. Over the gate G2 and the gate insulating film 3, an interlayer insulating film 4 and a planarization insulating film 5 which are equal to those shown in FIG. 2A are sequentially formed in a laminate structure. The interlayer insulating film 4 has an opening at a position corresponding to the drain D2, and by filling this opening with an conductive material such as aluminum, the drain D2 comes in electrical contact with the drive power source line IL. Also, a contact hole is formed through portions of the interlayer insulating film 4 and the planarization insulating film 5 which correspond to the source S2. Then, ITO (Indium Tin Oxide) is formed so as to fill this contact hole, so that the source S2 comes in electrical contact with an transparent electrode 11 made of ITO or the like. The transparent electrode 11 constitutes an anode of the EL element. It should be noted that the source S2 is not necessarily brought in direct contact with the ITO, and the source S2 and the ITO may be connected in the following manner, for example. That is, a contact hole is first formed in the interlayer insulating film 4 and the gate insulating film 3, and the hole is filled with a conductive material such as aluminum simultaneously with the formation of the contact (the drain electrode) between the drain D2 and the power source line IL. Then, another contact hole is formed at a corresponding portion of the planarization insulating film 5, which is subsequently formed, and ITO is formed so as to fill this contact hole.

As an example, the EL element may comprise the following layers sequentially accumulated in a laminate structure:

a) a transparent electrode 11;

b) a hole transporting layer 12 made of NBP;

c) an emissive layer 13 for red (R) obtained by doping a dopant of red color (DCJTB) into a host material (Alq₃), for green (G) obtained by doping a dopant of green color (Coumarin 6) into a host material (Alq₃), or for blue (B) obtained by doping a dopant of blue color (Perylen) into a host material (BAlq);

d) an electron transporting layer 14 made of Alq₃;

e) an electron injecting layer 15 made of lithium fluoride (LiF); and

f) an electrode (cathode) 16 made of aluminum (Al).

The abbreviations used in the above description refer to the following materials:

“NBP” refers to N,N′-di((naphthalene-1-yl)-N,N′-diphenylbenzidine);

“Alq₃” refers to tris(8-hydroxyquinolinato)aluminum;

“DCJTB” refers to (2-(1,1-dimethylethyl)-6-(2-(2,3,6,7-tetrahydro-1,1,7,7-tetramethyl-1H,5H-benzo[ij]quinolizin-9-yl)ethenyl)-4H-pyran-4-ylidene)propanedinitrile;

“Coumarin 6” refers to “3-(2-benzothiazolyl)-7-(diethylamino)coumarin; and

“BAlq” refers to (1,1′-bisphenyl-4-Olato)bis(2-methyl-8-quinolinplate-N1,08)Aluminum.

The hole transporting layer 12, the electron transporting layer 14, the electron injecting layer 15 and the electrode 16 are also formed in the regions shown in FIG. 2A as common layers. However, the emissive layer 13, which is formed in an individual island shape for each pixel so as to correspond to the transparent electrode 11, is not shown in FIG. 2A. It should be noted that, as shown in FIGS. 2A and 2B, an insulating film 10 is formed on the planarization insulating film 5.

An example method of manufacturing an EL display apparatus according to the present embodiment will now be described.

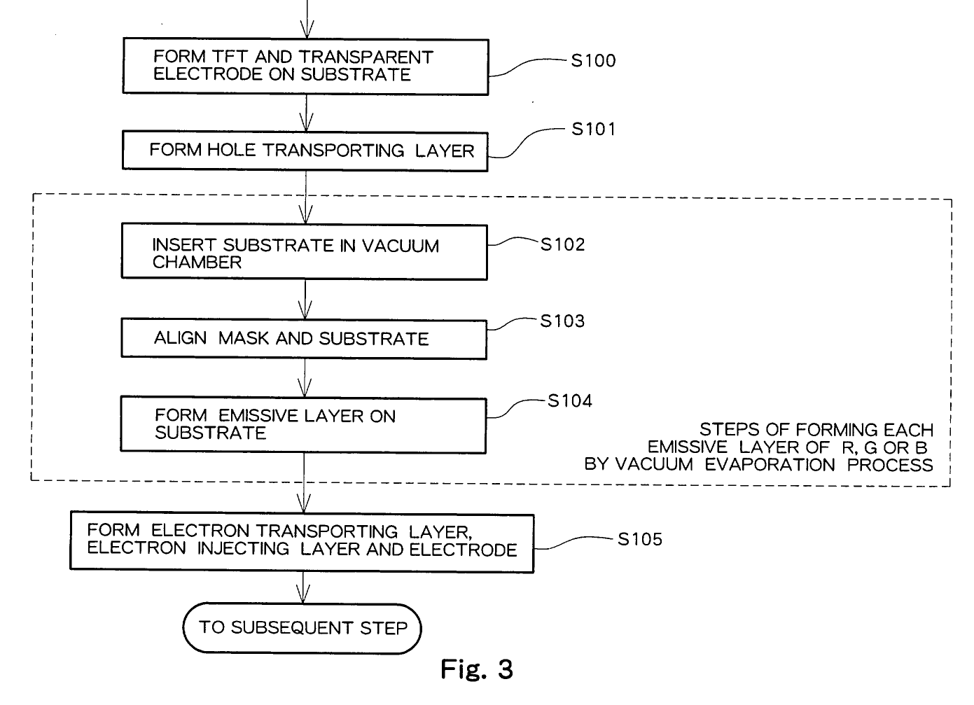

FIG. 3 shows the procedures for manufacturing an EL display apparatus according to the present embodiment. Referring to FIG. 3, this series of procedures starts with step s100 where a TFT and a transparent electrode 11 are formed on a glass substrate 1. Further, the hole transporting layer 12 is formed using vacuum evaporation or the like on substantially all the surface of the substrate 1 (step s101).

The glass substrate 1 on which the hole transporting layer 12 has been formed is then transported into a vacuum chamber which is used, in this example, for forming an emissive layer, without being exposed to the air (step s102). At this time, the substrate 1 is transported with the surface having the hole transporting layer 12 formed thereon facing downward. Inside the chamber, a mask 30 made, for example, of nickel (Ni) and having an opening (not shown) which has been previously formed so as to correspond to the shape of the emissive layer, is provided. Specifically, the mask 30 is fixedly secured to a holding plate 34 having an opening at least in the mask region, by means of a mask frame 31 provided on the holding plate 34.

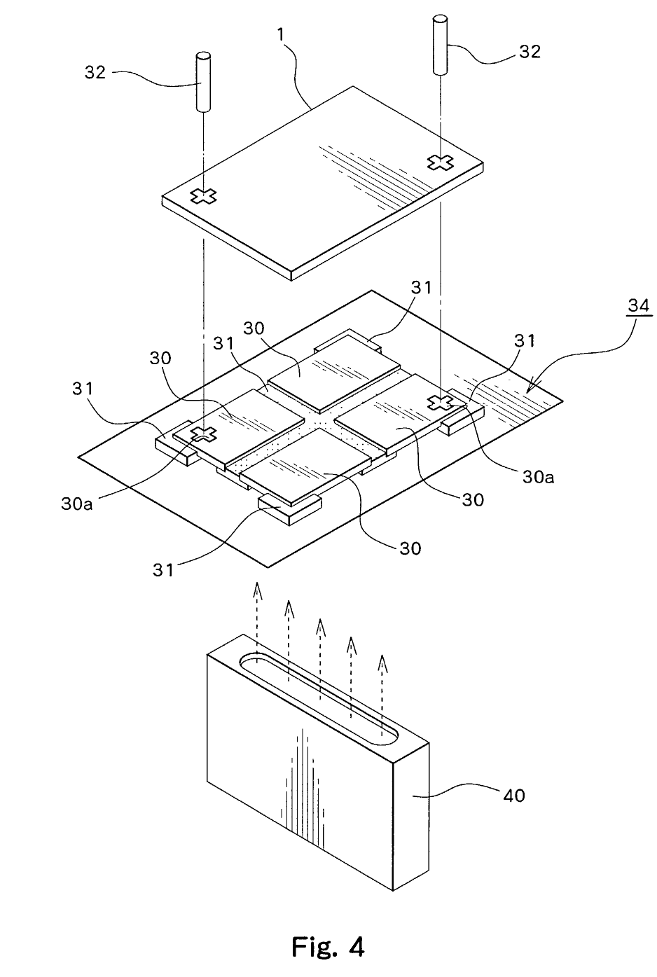

Once the glass substrate 1 having the hole transporting layer 12 formed thereon is inserted in the vacuum chamber, the glass substrate 1 and the mask 30 located below the substrate 1 are aligned. Specifically, while the position of an alignment mark 30a formed in the mask 30 and the position of an alignment mark 1a formed on the glass substrate 1 are monitored using a CCD (Charge Coupled Device) camera 32 or the like, the glass substrate 1 and the mask 30 are aligned with each other such that alignment marks 30a and 1a correspond with each other (step s103 in FIG. 3). Although these alignment marks 30a and 1a are shown in FIG. 4 in an enlarged manner for the convenience of drawing, the example marks are actually square crosses having 50 μm bars. Naturally, the shape and the size of the alignment mark is not limited to this example.

Actually, in the above steps, it is necessary to form pixels corresponding to three main colors R, G, and B on a single panel so as to obtain a color display apparatus. Therefore, the emissive layers for R, G, and B are to be formed individually. More specifically, when different emissive materials are used for each of R, G, and B, the glass substrate 1 on which the hole transporting layer 12 has been formed is inserted into each of the individual vacuum chambers in turn, for forming the emissive layer 13 corresponding to each of the primary colors R, G, and B. In each of these vacuum chambers, a mask having an opening at a portion corresponding to the transparent electrode (anode) 11 which is used for light emission of a predetermined primary color is provided as the above-described mask 30. Namely, a mask corresponding to one of the colors R, G, and B is provided in each of the vacuum chambers. It is therefore possible to form an emissive layer corresponding to each of the primary colors at a predetermined position, in each chamber.

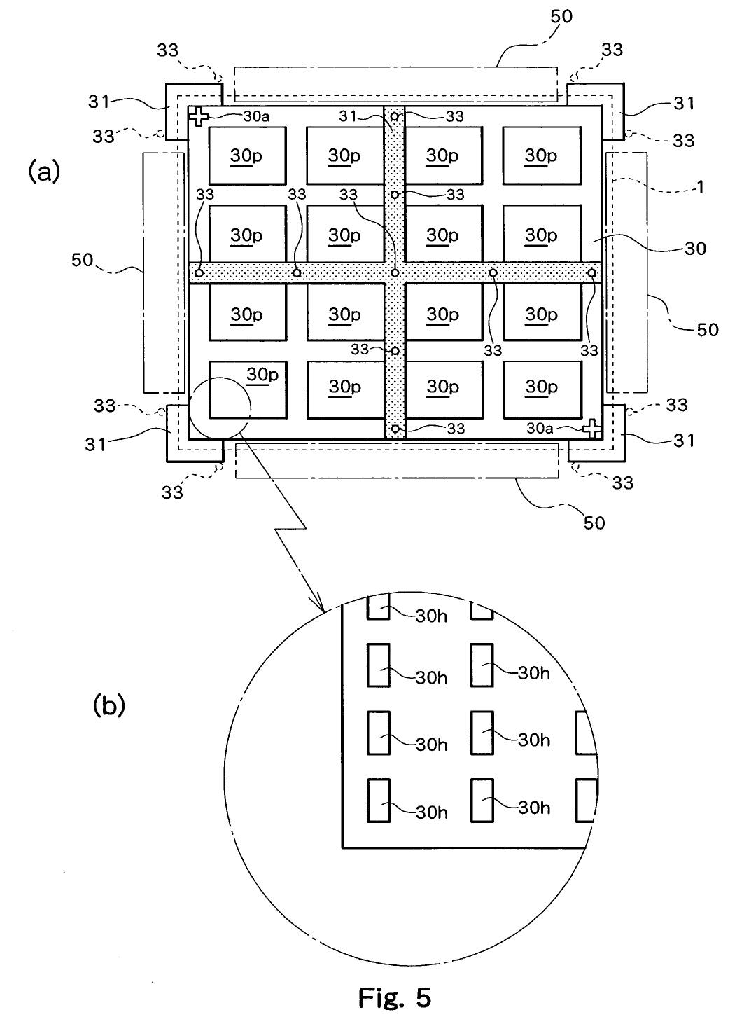

FIG. 5(a) shows how the glass substrate 1 (indicated by a dot line in this drawing) is aligned with respect to the mask 30. In this embodiment, the mask 30 is constituted so as to form a large number of display panels from a single glass substrate. More specifically, as illustrated in FIG. 5(a), the mask 30 according to this embodiment includes 16 panel forming sections 30p so as to form 16 display panels simultaneously. These 16 panel forming sections 30p are formed by 4 masks 30 each having 4 panel forming sections 30p. In each panel forming section 30p, openings 30h are formed in such a manner that each opening 30h corresponds to the transparent electrode 11 used for emission of light of a desired primary color.

When the mask 30 and the glass substrate 1 are aligned with each other as shown in FIG. 5(a), the glass substrate 1 is then supported by the mask frame 31 or the like. Then, by heating a material for the emissive layer 13 to evaporate from the evaporation source 40 located below the holding plate 34 as shown in FIG. 4, the material is deposited onto the surface of the glass substrate 1 through the openings of the mask (step s104).

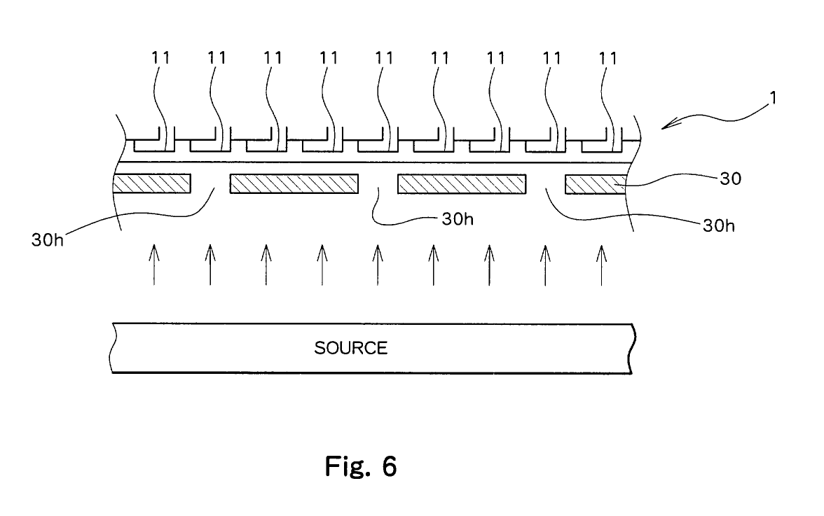

The formation of the emissive layer via the mask as described above is schematically shown in FIG. 6. Referring to FIG. 6, of the respective transparent electrodes (anodes) 11, portions other than regions where the transparent electrodes corresponding to a desired primary color for each chamber are formed, are covered with the mask 30. An EL material (an organic EL material) corresponding to the desired primary color is heated within the source, is evaporated, and is then deposited on the glass substrate 1 (to be specific, on the hole transporting layer 12) through the opening 30h of the mask 30.

After the emissive layer of the corresponding primary color is thus formed by evaporation within each chamber, the glass substrate 1 is removed from the vacuum chamber used for forming the emissive layer, and then transported into another vacuum chamber where the electron transporting layer 14, the electron injecting layer 15, and the electrode (cathode) 16 are formed (step s105 in FIG. 5). It should be noted that formation of the electron transporting layer 14, the electron injecting layer 15 and the electrode (cathode) 16 are carried out in separate chambers.

As described above, there is a problem that flexure is generated in the glass substrate 1 and the mask 30 when the glass substrate 1 and the mask 30 are aligned with each other within the vacuum chamber in a manner as described above. In particular, when a large size glass substrate 1 is used so as to form a plurality of display panels simultaneously as in the present embodiment, significant flexure is likely to be generated in the glass substrate 1.

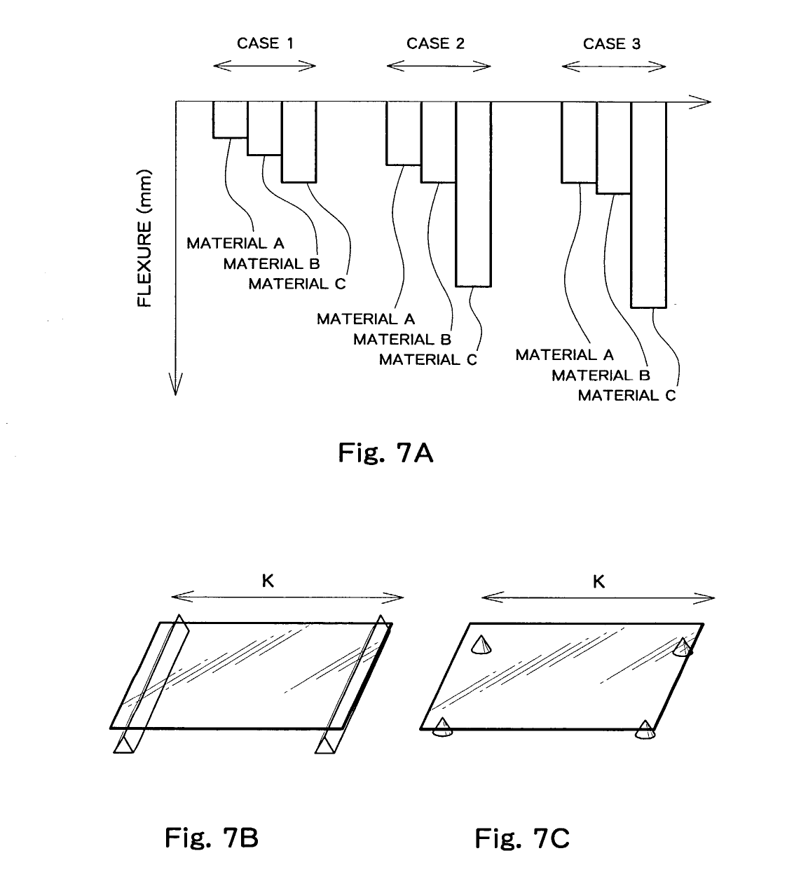

The relationship between the size and support type of the glass substrate and the flexure generated in the glass substrate will be described with reference to FIGS. 7A-7C.

FIG. 7A shows a relationship between the size and support type of a glass substrate and the flexure generated in the glass substrate. Referring to FIG. 7A, the case 1 indicates the amount of flexure of a glass substrate having a length K and made of one of different materials A, B, and C when the substrate is supported in a manner shown in FIG. 7B. The case 2 indicates the amount of flexure of a glass substrate having a length L (L>K) and made of one of different materials A, B, and C when the substrate is supported in a manner shown in FIG. 7B. The case 3 indicates the amount of flexure of a glass substrate having a length K and made of one of different materials A, B, and C when the substrate is supported in a manner shown in FIG. 7C.

As is obvious from FIG. 7A, compared to when the glass substrate is point supported (FIG. 7C), flexure can be reduced to a greater extent when the glass substrate is supported along its sides (FIG. 7B). It can also be seen from FIG. 7A that the shorter the glass substrate, the less flexure will be produced. When the gravitational acceleration is g, the Poisson ratio is σ, the density of the glass is ρ, the Young's modulus of the glass is E, and the thickness of the glass is t, the flexure n generated when a glass substrate is supported in a manner shown in FIG. 7B can be expressed by the following equation (c1):

n=K⁴gρ(1−σ²)/6.4Et² (c1)

As can be seen from the above equation (c1), as the length of the glass substrate increases, the amount of flexure will drastically increase.

Accordingly, in this embodiment, at the time of alignment of the glass substrate 1 and the mask 30, the upper surface of the glass substrate 1 is supported using electrostatic adsorption. Namely, within a vacuum chamber, it is not possible to support the upper surface of the glass substrate 1 by, for example, suction using a pressure lower than the air. Accordingly, by supporting the upper surface of the glass substrate 1 by electrostatic adsorption, supporting of the glass substrate 1 by adsorption can be achieved even in the vacuum chamber.

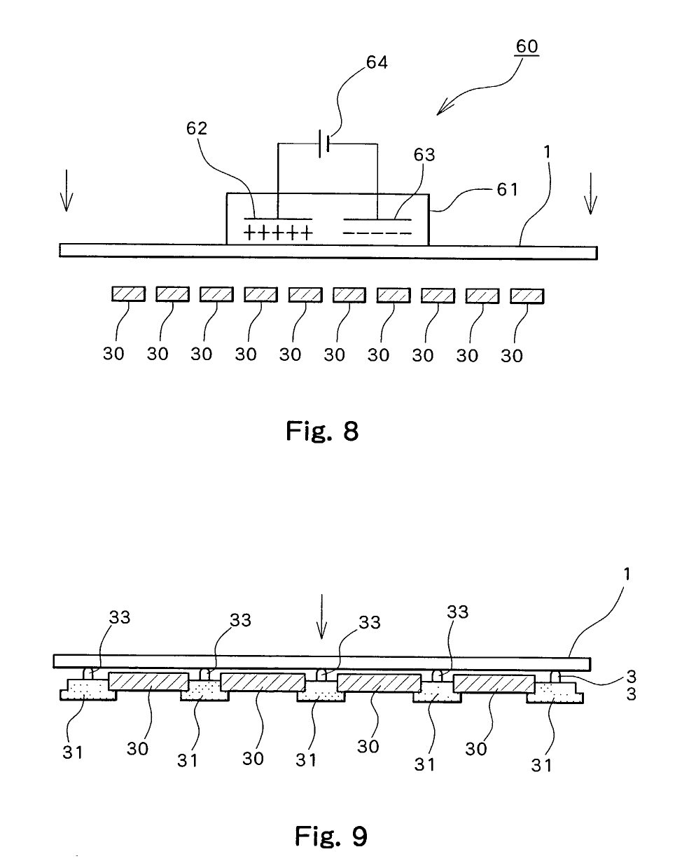

FIG. 8 shows the principle of the electrostatic adsorption. Referring to FIG. 8, an electrostatic adsorption device 60 used in this embodiment comprises a pair of electrodes 62, 63 provided in the adsorption section 61 made of ceramic or the like and a battery 64 whose anode and cathode are connected to the pair of electrodes 62, 63, respectively. By supporting the glass substrate 1 by means of adsorption using the electrostatic adsorption device 60, it is possible to further reduce the flexure generated in the glass substrate 1.

According to the foregoing embodiment, the following advantage can also be achieved.

(1) Because the upper surface of the glass substrate 1 is supported by electrostatic adsorption, it is possible, at the time of alignment between the glass substrate 1 and the mask 30, to still further suppress the generation of flexure in the glass substrate 1 and accordingly to appropriately align the glass substrate 1 with the mask 30.

(Second Embodiment)

A second embodiment of a method of manufacturing an EL display apparatus of the present invention, which is implemented as a method of manufacturing an active matrix type color EL display apparatus, will be described mainly with regard to the difference from the above-described first embodiment, and with reference to the drawings.

In this second embodiment, at the time of alignment of the glass substrate 1 and the mask 30, a supporting method for a substrate as will be described below is also used.

More specifically, as shown in FIG. 5(a), a plurality of pins 33 made of a resin, a metal, or the like are provided on the mask frame 31. The contact surface of each pin 33 which abuts the glass substrate 1 is spherical, as shown in FIG. 9. While the glass substrate 1 and the mask 30 are aligned with each other, the glass substrate is supported by these spherical contact surfaces, especially in the center region of the glass substrate 1, thereby suppressing flexure at the time of alignment without damaging the glass substrate 1. It should be noted that the pins 33 are arranged symmetrically with regard to the surface of the glass substrate 1.

More specifically, these pins 33 are preferably arranged symmetrically with respect to the surface of the glass substrate 1. More specifically, in the example shown in FIG. 5(a), these pins 33 are equally spaced such that they divide the surface of the glass substrate 1 into equal areas, both vertically and horizontally. Further, in the example of FIG. 5(a), the pins 33 are disposed such that each pin is located at a midpoint between a pair of the panel forming parts 30p. With this arrangement, even when the glass substrate 1 is bent to some extent due to the contact between the glass substrate 1 and a pin 33, toward the panel region 30p adjacent to the pin 33, the influence of such flexure can be substantially disregarded. These pins 33 are not disposed inside the panel regions 30p, and are evenly distributed at regular intervals in the remaining regions, especially in the center region of the glass substrate 1. In the example of FIG. 5(a), the pins 33 are arranged so as to equally divide the length of each side of the glass substrate 1. It should be noted that, when a single panel is formed from a single glass substrate 1, these pins are disposed within the display region and that, in such a case, the pins 33 are disposed as evenly as possible at positions where no mask openings are formed.

Further, in this embodiment, the pin 33 is made capable of expansion and contraction by, for example, including a spring, such as a a flat spring, at the lower portion. Therefore, the pin 33 can be contracted due to the weight of the glass substrate 1 to thereby appropriately support the glass substrate 1. Further, the pin 33 is designed to be contractable to the level of the mask frame 31, so that, after completion of the alignment, the pin 33 can be contracted to a level substantially equal to that of the upper surface of the mask 30 due to the weight of the glass substrate 1 or an external force. In addition, when the pin 33 is designed such that the height of the pin 33, even when contracted, is higher than the level of the mask 30, it is possible to maintain a gap between the mask 30 and the glass substrate 1, to thereby more reliably prevent the glass substrate 1 from being damaged by the mask 30.

According to the second embodiment as described above, the following advantages can be achieved in addition to the above-described advantage (1) of the first embodiment.

(2) By performing the alignment of the glass substrate 1 and the mask 30 while the glass substrate 1 is being supported by the pins 33, it is possible to more reliably or to a greater extent prevent the generation of flexure in the glass substrate 1.

(3) Because the pin 33 is designed such that it is capable of expansion and contraction in the vertical direction, after the glass substrate 1 and the mask 30 are aligned, it is possible to smoothly support the glass substrate 1 by the mask 30 or the like, and also to maintain a gap between the mask 30 and the glass substrate 1.

The second embodiment may be modified as follows.

The arrangement of the pins 33 is not limited to the above-described example, and the pins 33 can be arranged in any other manner as long as the pins 33 can support the glass substrate 1 in the region other than the display region. Alternatively, it is also possible to provide the pins 33 on the holding plate 34 of the mask frame 31 rather than on the mask frame 31, as shown in FIG. 5(a) by a dotted line.

The features of the pin 33 are not limited to the capability of expansion and contraction as described. When the pin 33 is not capable of expansion and contraction, the alignment and the evaporation of the EL material may, for example, be performed with the glass substrate 1 being supported by these pins 33.

(Third Embodiment)

A third embodiment of a method of manufacturing an EL display apparatus of the present invention, which is implemented as a method of manufacturing an active matrix type color EL display apparatus, will be described mainly with regard to differences from the above-described second embodiment, and with reference to the drawings.

In the third embodiment, during alignment of the glass substrate 1 and the mask 30 according to the second embodiment, a supporting method for a substrate as will be described below is simultaneously implemented.

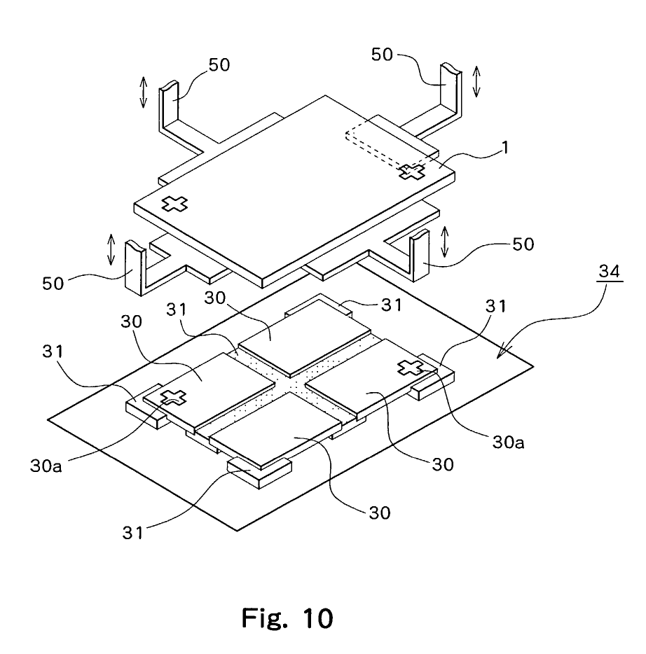

Specifically, according to the present embodiment, four sides of the glass substrate 1 are supported by means of side supporting members 50 in a manner shown in FIG. 10, so as to inhibit the flexure generated in the glass substrate 1. More specifically, as described above with reference to FIGS. 7A to 7C, because the longer the unsupported side of the glass substrate, the greater the flexure of the glass substrate, increased flexure resulting from increase in the length of the glass substrate 1 is suppressed by supporting the four sides of the glass substrate 1.

Further, the four sides of the glass substrate 1 are supported by the side supporting members 50 such that the side supporting members 50 which face each other and support each pair of opposing sides of the glass substrate 1 are disposed as symmetrically as possible, thereby further inhibiting the generation of flexure in the glass substrate 1. More specifically, a pair of side supporting members 50 supporting the opposing sides of the glass substrate 1 are designed to be the same size and of symmetrical shape to the greatest possible extent. Also, all the supporting members 50 are coordinated such that the levels of their supporting surfaces are aligned. The operation of the four supporting members 50 can be controlled individually or, for example, for each pair of opposing members 50. Further, when the glass substrate 1 and the mask 30 are aligned with each other, it is preferable that the plurality of supporting members 50 be adjusted to prevent their relative positions from being misaligned.

Also, according to the present embodiment, each of the supporting members 50 supports an edge side of a surface of the glass substrate 1 which faces the mask 30. By supporting the glass substrate 1 by the side supporting members 50 along each side in a line supporting manner, it is possible to support the glass substrate 1 without the side supporting members 50 contacting the display region of the glass substrate 1.

More specifically, as shown in FIG. 10, each of the side supporting members 50 has an L shape. The glass substrate 1 is supported by the side supporting members 50, with the element forming surface of the glass substrate 1, in this example, a surface on which the hole transporting layer 12 has been formed, facing downward and setting on the end portion (contact and support portion) of the L shaped members 50.

The length of each side supporting member 50 is designed to be shorter than each side of the glass substrate 1. More specifically, the length of the portion of the side supporting member 50 on which the glass substrate 1 is disposed is made shorter than the interval between two adjacent mask frames 31 of the mask frames 31 provided corresponding to the periphery of the glass substrate 1. It is thereby possible to prevent interference between the mask frames 31 and the side supporting members 50, as shown in FIG. 5(a). After the alignment between the glass substrate 1 and the mask 30 is completed, the glass substrate is supported by the mask frames 31 and the side supporting members 50 are removed. By setting the length of the side supporting members 50 as described above, the glass substrate 1 can be supported by the side supporting members 50 at positions indicated in FIG. 5(a) by one dotted chain line. It is also possible to remove the side supporting members 50 in a simple manner without making the supporting members 50 contact with the mask frames 31, by, for example, withdrawing each supporting member 50 in the direction parallel to the lower surface of the glass substrate 1 and away from the substrate 1.

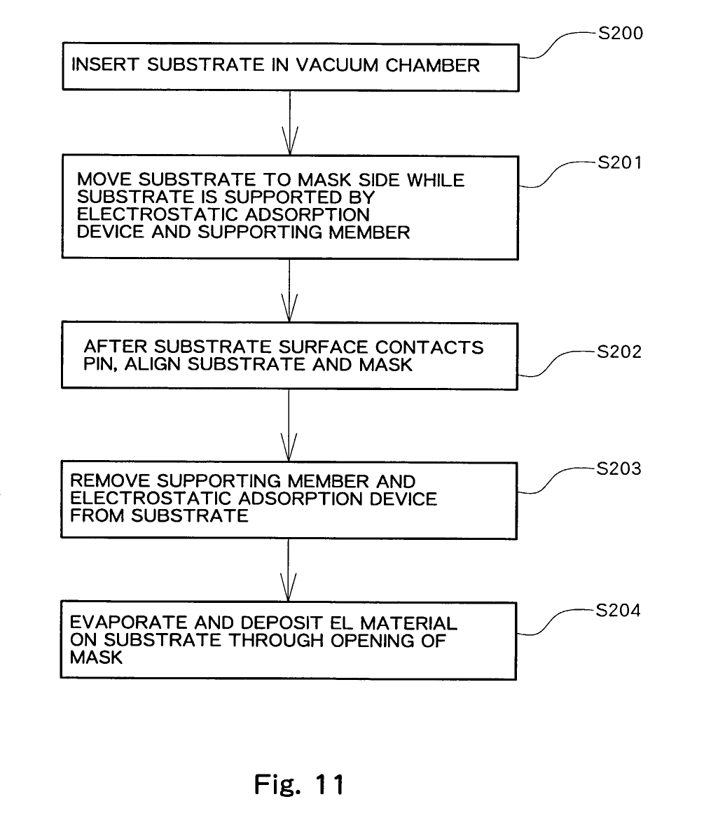

Referring to FIG. 11, the procedure for alignment between the glass substrate 1 and the mask 30 according to the present embodiment will be summarized.

In this procedure, when the glass substrate 1 is inserted into a vacuum chamber (step s200), the glass substrate 1 is moved toward the mask 30 side with the glass substrate 1 being supported by the electrostatic adsorption device 60 and the supporting members 50 (step s201). Then, after the glass substrate 1 comes into contact with the pins 33, the glass substrate 1 is aligned with the mask 30 (step s202). When the alignment is complete, the glass substrate 1, which is at this point supported by the electrostatic adsorption device 60 and the supporting members 50, is lowered. Then, with the glass substrate being supported by the mask 30 or the pins 33, the electrostatic adsorption device 60 and the supporting members 50 are removed (step s203). The EL material is then deposited to the glass substrate 1 which has been thus aligned with the mask 30 and then supported by the glass frames 31 (step s204).

According to the third embodiment described above, the following advantage can be further achieved in addition to the above advantage (1) of the first embodiment and the advantages (2) and (3) of the second embodiment.

(4) Because the glass substrate 1 and the mask 30 are aligned with each other while the four sides of the glass substrate 1 is being supported by the side supporting members 50, it is possible to suppress the flexure generated in the glass substrate 1 more suitably.

The third embodiment may be modified as follows.

The EL material may be evaporated and deposited onto the glass substrate 1 while the glass substrate 1 remains supported by the side supporting members 50. At this time, the glass substrate 1 may be further supported using electrostatic adsorption simultaneously. Alternatively, it is also possible to evaporate and deposit the EL material onto the glass substrate 1 while the glass substrate 1 is supported only by electrostatic adsorption. In these cases, the shape of the mask frame 31 may be arbitrarily chosen.

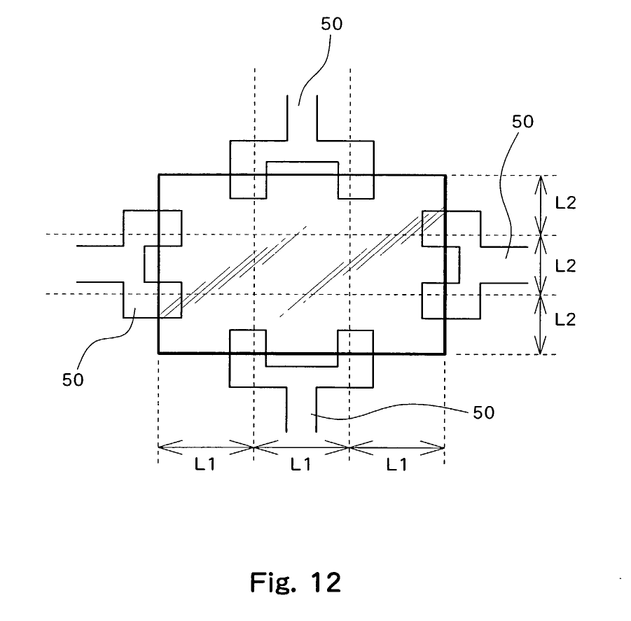

Further, supporting members other than the side supporting members 50 may also be used for supporting the four sides of the glass substrate 1. For example, as shown in FIG. 12, a supporting member which supports two trisecting points on each side of the glass substrate, which is trisected at equal intervals, may be used. With this structure, it is similarly possible to support four sides of a glass substrate to thereby reduce the flexure when the length of a side is increased. Any method of supporting four sides other than that shown in FIG. 12 may be also used. In all cases, however, it is preferable that the support portions are symmetrical.

It is also possible to support at lease three sides of a glass substrate rather than all four sides.

(Other Embodiments)

The following variations may be employed with any of the above-described embodiments.

The mask arrangement for providing a plurality of display panels is not limited to the example shown in FIG. 5 in which a mask is divided into four parts. When the mask is changed, the mask frame may be appropriately changed as necessary into a suitable shape capable of fixing the mask.

A plurality of display panels need not necessarily be formed simultaneously.

Further, the structure of the mask frame 31 is also not limited to the example shown in FIG. 5(a)

The present invention is not limited to use with a vacuum evaporation process, and is effective for reducing the flexure generated in the glass substrate when alignment is performed between an EL element forming substrate such as a glass substrate and a mask.

The layer of an EL element which is formed for each R, G, and B region using a mask is not limited to an emissive layer. For example, when it is desired to vary the deposition amount for forming a hole transporting layer or an electron transporting layer among R, G and B, it is effective to form these layers via a mask as in the formation of the emissive layer according to each of the above-described embodiments. Accordingly, the present invention can also be effectively applied to the alignment between the substrate and the mask in such a case.

The present invention is not limited to use for an active matrix type EL display apparatus, but is effective for manufacturing an EL display apparatus of any type such as a passive matrix type.

The method of supporting the glass substrate 1 by adsorption is not limited to an electrostatic adsorption method. When alignment between the glass substrate 1 and the mask 30 is performed other than within a vacuum chamber, a supporting method such as a vacuum adsorption method may be appropriately adopted as necessary or desired.

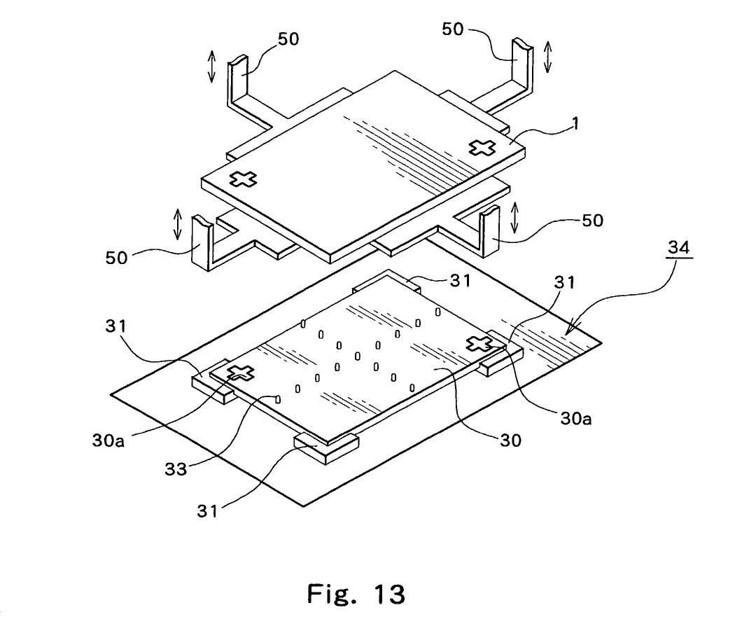

In the preceding description, as shown in FIGS. 4 and 5(a) or the like, a plurality of masks 30 are fitted in and positioned on the mask frames 31, so that these masks 30 can be used as an evaporation mask for a single large-size glass substrate. Alternatively, it is also possible to use a single mask 30 for a single glass substrate, as shown in FIG. 13. The mask 30 is fit into the mask frames 31 disposed corresponding to four corners of the mask 30, and is thereby positioned on the mask frames 31. Within an evaporation chamber, the glass substrate 1 is disposed above the mask 30 thus positioned. The glass substrate 1 is then aligned with the mask 30 using the alignment mark formed on the glass substrate 1 and the alignment mark on the mask 30, while at least three sides (four sides, in FIG. 13) of the glass substrate 1 are being supported by the side supporting members 50. It should be noted that, in the example shown in FIG. 5(a), the pins 33 for supporting the glass substrate 1 at the time of alignment between the substrate and the mask and of vacuum evaporation, are formed on the mask frame 31. In the example shown in FIG. 13 in which a single mask 30 is used, no mask frames 31 are located in the center portion of the mask 30 (even if the mask frames 31 are located in the center portion of the mask 30, such mask frames 31 do not appear on the surface (the upper surface) of the mask 30 opposing to the glass substrate 1). Accordingly, in such a case, the pins 33 are formed on the mask 30 at the non-opening sections, namely at the non-display region other than the openings 30h as shown in FIG. 5(b).

While the preferred embodiments of the present invention have been described using specific terms, such description is for illustrative purposes only, and it is to be understood that changes and variations may be made without departing from the spirit or scope of the appended claims.

What is claimed is:

1. A method of manufacturing an electroluminescence display apparatus, in which
after a substrate and a mask disposed below the substrate are aligned with each other while an upper surface of the substrate is supported by adsorption, a material of an electroluminescence element is adhered to the substrate through an opening of the mask to form an electroluminescence element layer.

2. An electroluminescence display apparatus according to claim 1, wherein
the mask is fixed and positioned prior to alignment of the substrate and the mask, and
the substrate which is supported by adsorption is moved so that the substrate is aligned with the mask.

3. An electroluminescence display apparatus according to claim 2, wherein
the mask is fixed and positioned onto a mask frame which is disposed on a holding table.

4. An electroluminescence display apparatus according to claim 1, wherein
at least the alignment of the substrate and the mask is performed within a vacuum chamber.

5. A method of manufacturing an electroluminescence display apparatus according to claim 4, wherein
said vacuum chamber is an evaporation chamber for the electroluminescence element layer.

6. A method of manufacturing an electroluminescence display apparatus according to claim 4, wherein
an upper surface of the substrate is supported by adsorption mechanism during alignment of the substrate and the mask.

7. A method of manufacturing an electroluminescence display apparatus according to claim 1, wherein
at least three sides of the substrate are further supported by side supporting members during alignment of the substrate and the mask.

8. A method of manufacturing an electroluminescence display apparatus according to claim 1, wherein
the mask is fixed and positioned on a mask frame prior to the alignment of the substrate and the mask, and
the substrate is then aligned with the mask while the substrate which is supported by adsorption is further supported on the mask using a plurality of pins provided on the mask frame.

9. A method of manufacturing an electroluminescence display apparatus according to claim 1, wherein
the mask is fixed and positioned on a mask frame disposed on a supporting table prior to the alignment of the substrate and the mask, and
the substrate is then aligned with the mask while the substrate which is supported by adsorption is further supported on the mask using a plurality of pins provided on at least one of the mask frame and the supporting table.

10. An electroluminescence display apparatus according to claim 9, wherein
at least the alignment of the substrate and the mask is performed within a vacuum chamber.

11. A method of manufacturing an electroluminescence display apparatus according to claim 10, wherein
said vacuum chamber is an evaporation chamber for the electroluminescence element layer.

12. A method of manufacturing an electroluminescence display apparatus according to claim 9, wherein
an upper surface of the substrate is supported by adsorption mechanism during the alignment of the substrate and the mask.

13. A method of manufacturing an electroluminescence display apparatus according to claim 9, wherein
the plurality of pins are capable of expansion and contraction in a vertical direction.

14. A method of manufacturing an electroluminescence display apparatus according to claim 9, wherein
at least three sides of the substrate are further supported by side supporting members during the alignment of the substrate and the mask.
